(19) United States
(12) Patent Application Publication
(10) Pub. No.: US 2026/0018318 A1
(43) Pub. Date: Jan. 15, 2026

(54) PIPELINE

(71) Applicant: Eric Edward Mimmo, South Hamilton, MA (US)

(72) Inventor: Eric Edward Mimmo, South Hamilton, MA (US)

(21) Appl. No.: 18/768,488

(22) Filed: Jul. 10, 2024

(51) Int. Cl. H01B 7/42; H05K 7/20

(52) U.S. Cl. CPC H01B 7/423; H05K 7/20281

(57) ABSTRACT

A transmission pipeline for cooling high voltage powerlines with a liquid. The pipeline comprises a maintenance access valve installed on the pipeline for adding or removing the oil from the pipeline. A maintenance manifold is installed on the maintenance access valve for all purposes regarding the maintenance necessary for the pipeline at that location. A manual service shut off valve is disposed on the outlet side of the manifold. A clear hose is mounted at a first end to the outlet of the manual service shut off valve. The clear hose mounted at a second end to a manual shutoff valve disposed on a tank within maintenance service equipment. A liquid detection sensor installed between the clear hose and the manual shut off valve. An electric powered shutoff valve is installed between the liquid detection sensor and the manual shutoff valve. A pump motor is connected to an outlet of the tank. An exhaust pipe is mounted to an outlet of the pump.

### FIELD OF THE INVENTION

The present invention relates to a system to protect the equipment and environment from a fluid leak from a pipe line filled with fluid during construction, maintenance and repair.

### BACKGROUND OF THE INVENTION

Electric transmission lines which are installed underground, rather than overhead on poles or towers. Due to their different physical, environment, and construction needs, underground transmission generally costs more and may be more complicated to construct than overhead lines.

The design and construction of underground transmission differ from overhead lines because of two significant technical challenges that need to be overcome. These are: 1) providing sufficient insulation so that cables can be within inches of grounded material; and 2) dissipating the heat produced during the operation of the electrical cables. Overhead lines are separated from each other and surrounded by air. Open air circulating between and around the conductors cools the wires and dissipates heat very effectively. Air also provides insulation that can recover if there is a flashover. In contrast, a number of different systems, materials, and construction methods have been used during the last century in order to achieve the necessary insulation and heat dissipation required for undergrounding transmission lines.

The cable was fluid-filled and paper insulated. The fluid was necessary to dissipate the heat. For decades, reliability problems continued to be associated with constructing longer cables at higher voltages. The most significant issue was maintenance difficulties.

Ther are two main types of underground transmission lines currently in use. One type is constructed in a pipe with fluid or gas pumped or circulated through and around the cable in order to manage heat and insulate the cables. The other type is a solid dielectric cable which requires no fluids or gas and is a more recent technological advancement.

The common types of underground cable construction include: High-pressure, fluid-filled pipe (HPFF) High-pressure, gas-filled pipe (HPGF) Self-contained fluid-filled (SCFF) Solid cable, cross-linked polyethylene (XLPE) High-Pressure, Fluid-Filled Pipe-Type Cable. A high-pressure, fluid-filled (HPFF) pipe-type of underground transmission line, consists of a steel pipe that contains three high-voltage conductors.

With a typical HPFF pipe-type cable, each conductor is made of copper or aluminum; insulated with high-quality, oil-impregnated kraft paper insulation; and covered with metal shielding (usually lead) and skid wires (for protection during construction).

With a HPFF or HPGF, a Pipe-Type Cross Section Welded Externally Coated Steel Pipe contains pressurized gas or fluid (usually nitrogen or synthetic oil) at 200 psi. With segmented copper conductor paper insulation metallic shield inside steel pipes, three conductors are surrounded by a dielectric oil which is maintained at 200 pounds per square inch (psi). This fluid acts as an insulator and does not conduct electricity.

The pressurized dielectric fluid prevents electrical discharges in the conductors' insulation. An electrical discharge can cause the line to fail. The fluid also transfers heat away from the conductors. The fluid is usually static and removes heat by conduction. In some situations, the fluid is pumped through the pipe and cooled through the use of a heat exchanger. Cables with pumped fluids require aboveground pumping stations, usually located within substations. The pumping stations monitor the pressure and temperature of the fluid. There is a radiator-type device that moves the heat from the underground cables to the atmosphere. The oil is also monitored for any degradation or trouble with the cable materials. The outer steel pipe protects the conductors from mechanical damage, water infiltration, and minimizes the potential for oil leaks.

Inside electrical transmission pipes, three conductors are surrounded by a dielectric oil which is maintained at 200 pounds per square inch (psi). This fluid acts as an insulator and does not conduct electricity. The pressurized dielectric fluid prevents electrical discharges in the conductors' insulation. An electrical discharge can cause the line to fail. The fluid also transfers heat away from the conductors. The fluid is usually static and removes heat by conduction. In some situations, the fluid is pumped through the pipe and cooled through the use of a heat exchanger. Cables with pumped fluids require aboveground pumping stations, usually located within substations. The pumping stations monitor the pressure and temperature of the fluid. There is a radiator-type device that moves the heat from the underground cables to the atmosphere. The oil is also monitored for any degradation or trouble with the cable materials. The outer steel pipe protects the conductors from mechanical damage, water infiltration, and minimizes the potential for oil leaks. The pipe is protected from the chemical and electrical environment of the soil by means of a coating and cathodic protection.

Underground transmission construction can be very site-specific, especially for higher voltage lines. Components of underground transmission are often not interchangeable as they are for overhead. Cable repairs costs for an underground line are usually greater than costs for an equivalent overhead line.

### SUMMARY OF THE INVENTION

According to an embodiment of the present invention, there is disclosed a transmission pipeline for cooling high voltage powerlines with a liquid. The pipeline comprises a maintenance access valve installed on the pipeline for adding or removing the oil from the pipeline. A maintenance manifold is installed on the maintenance access valve for all purposes regarding the maintenance necessary for the pipeline at that location. A manual service shut off valve is disposed on the outlet side of the manifold. A clear hose is mounted at a first end to the outlet of the manual service shut off valve. The clear hose mounted at a second end to a manual shutoff valve disposed on a tank within maintenance service equipment. A liquid detection sensor installed between the clear hose and the manual shut off valve. An electric powered shutoff valve is installed between the liquid detection sensor and the manual shutoff valve. A pump motor is connected to an outlet of the tank. An exhaust pipe is mounted to an outlet of the pump.

### BRIEF DESCRIPTION OF THE DRAWINGS

The structure, operation, and advantages of the present invention will become further apparent upon consideration of the following description taken in conjunction with the accompanying figures (FIGs.). The figures are intended to be illustrative, not limiting. Certain elements in some of the figures may be omitted, or illustrated not-to-scale, for illustrative clarity. The cross-sectional views may be in the form of “slices”, or “near-sighted” cross-sectional views, omitting certain background lines which would otherwise be visible in a “true” cross-sectional view, for illustrative clarity.

In the drawings accompanying the description that follows, both reference numerals and legends (labels, text descriptions) may be used to identify elements. If legends are provided, they are intended merely as an aid to the reader, and should not in any way be interpreted as limiting.

These and other objects and advantages of the invention will become apparent from the following description and from the accompanying drawings which illustrate one embodiment of the invention.

FIG. 1 is a side view of a transmission pipeline connected to a maintenance access point with a manual shut-off valve extending through maintenance service equipment, in accordance with the present invention.

### DETAILED DESCRIPTION OF THE PREFERRED EMBODIMENTS

In the description that follows, numerous details are set forth in order to provide a thorough understanding of the present invention. It will be appreciated by those skilled in the art that variations of these specific details are possible while still achieving the results of the present invention. Well-known processing steps are generally not described in detail in order to avoid unnecessarily obfuscating the description of the present invention.

In the description that follows, exemplary dimensions may be presented for an illustrative embodiment of the invention. The dimensions should not be interpreted as limiting. They are included to provide a sense of proportion. Generally speaking, it is the relationship between various elements, where they are located, their contrasting compositions, and sometimes their relative sizes that is of significance.

In the drawings accompanying the description that follows, often both reference numerals and legends (labels, text descriptions) will be used to identify elements. If legends are provided, they are intended merely as an aid to the reader, and should not in any way be interpreted as limiting.

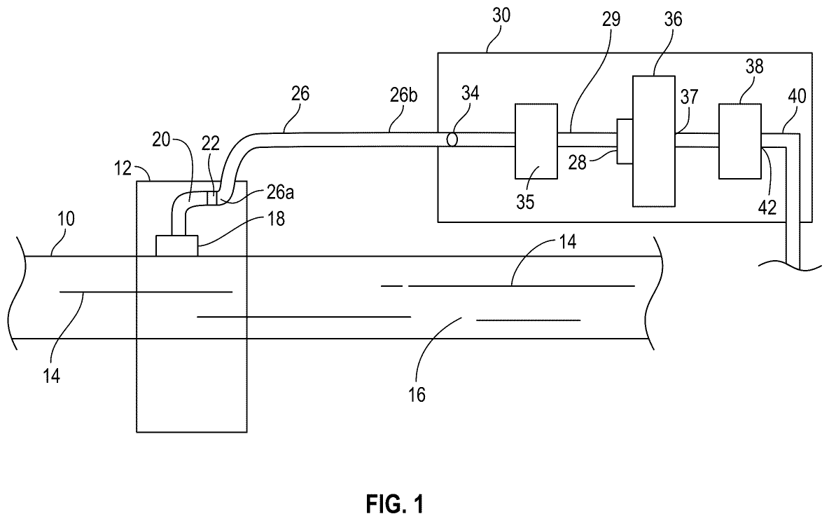

Referring to FIG. 1, there is illustrated a transmission pipeline 10 extending below a manhole 12. The transmission line can carry a number of high voltage powerlines 14 which are cooled with a liquid such as oil 16 that flows through the pipeline. A maintenance access valve 18 for adding or removing the oil from the pipe line is permanently installed to the pipeline at a location below the manhole 12. The maintenance access valve 18 is permanently installed and only replaced from pipeline 10 due to internal failure. A maintenance manifold 20 can then be installed depending for all purposes regarding the maintenance necessary for the pipeline at that location.

A manifold 20 is attached to the outlet of the maintenance access valve 18. A manual service shut off valve 22 at the end of the manifold 20 is disposed on the outlet side of the manifold. A clear hose 26 is mounted at one end 26a to the outlet of the service shut valve manifold. The outlet 26b of the clear hose 26 is attached to the manual shutoff valve 28 disposed on a tank 36 within the maintenance service equipment 30.

A liquid detection sensor 34 is installed between the clear hose 26 and the manual shut off valve 28. An electric powered shutoff valve 35 is installed between the liquid detection sensor 34 and the shutoff valve 28. The maintenance service equipment device 30 contains a tank 36 connected to the inlet side 29 of the maintenance service equipment device 30. A pump motor 38 is connected to the outlet 37 of the tank 36. An exhaust pipe 40 is mounted to the outlet 42 of pump 38.

The electric powered shutoff valve 35 is normally closed when no power is applied to the valve 35 and open when power is applied to the valve 35. The liquid detection sensor 34 communicates with the electric powered shutoff valve 35 when liquid is present so the valve 35 can automatically close to protect the equipment in the maintenance service equipment device 30 and the environment outside of the device 30 by preventing oil from entering the equipment and flowing into the environment.

In the event of human error, if oil were to enter the maintenance service equipment device 30 and exit through its exhaust 40, the result would be the destruction of the maintenance service equipment 30 and a huge environment disaster with oil on the ground until the valve is shutoff.

Prior to the system being made operational, i.e. to add oil to the pipeline 10, the pipeline 10 is initially free of oil. All maintenance access valves 18 along the pipeline 10 are opened and connected to equipment device 30. The equipment device 30 is operated to draw the atmosphere and any other contaminants from the new pipeline. When levels within the pipeline are acceptable, the filing of oil process of the pipeline 10 can proceed.

During the filing process, as oil reaches each device 30, the valves at the devices 30 need to be closed in order to prevent equipment failure and environmental disasters.

Once the entre pipeline 10 has been filled with total allotment of oil, then all valves 18 are closed, the manifolds 20 are closed and all equipment removed. Plugs are installed on valve 18 and the pipeline 10 is made ready to begin the steps to be put into service.

Although the invention has been shown and described with respect to a certain preferred embodiment or embodiments, certain equivalent alterations and modifications will occur to others skilled in the art upon the reading and understanding of this specification and the annexed drawings. In particular regard to the various functions performed by the above described components (assemblies, devices, etc.) the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several embodiments, such feature may be combined with one or more features of the other embodiments as may be desired and advantageous for any given or particular application.

1. A transmission pipeline for cooling high voltage powerlines with a liquid, comprising:
a maintenance access valve installed on the pipeline for adding or removing the oil from the pipeline;
a maintenance manifold installed on the maintenance access valve depending for all purposes regarding the maintenance necessary for the pipeline at that location;
a manual service shut off valve disposed on the outlet side of the manifold;
a clear hose mounted at a first end to the outlet of the manual service shut off valve;
the clear hose mounted at a second end to a manual shutoff valve disposed on a tank within maintenance service equipment;
a liquid detection sensor installed between the clear hose and the manual shut off valve;
an electric powered shutoff valve installed between the liquid detection sensor and the manual shutoff valve;
a pump motor connected to an outlet of the tank; and
an exhaust pipe mounted to an outlet of the pump.

2. The transmission pipeline for cooling high voltage powerlines of claim 1 wherein the electric powered shutoff valve is normally closed when no power is applied to the electric powered shutoff valve.

3. The transmission pipeline for cooling high voltage powerlines of claim 2 wherein the liquid detection sensor communicates with the electric powered shutoff valve when liquid is present.

4. The transmission pipeline for cooling high voltage powerlines of claim 3 wherein the electric powered shutoff valve can automatically close to protect the equipment in the maintenance service equipment device.

5. The transmission pipeline for cooling high voltage powerlines of claim 4 wherein the electric powered shutoff valve can automatically close to protect environment outside of the maintenance service equipment device by preventing oil from flowing into the environment.

6. The transmission pipeline for cooling high voltage powerlines of claim 5 wherein once the entre pipeline has been filled with a total allotment of oil, then all valves are closed, the manifolds is closed and all equipment is removed.

7. The transmission pipeline for cooling high voltage powerlines of claim 6 wherein prior to the pipeline being made operational, all maintenance access valves along the pipeline are opened and connected to equipment device.

8. The transmission pipeline for cooling high voltage powerlines of claim 7 wherein the equipment device is operated to draw the atmosphere and any other contaminants from the pipeline.

9. The transmission pipeline for cooling high voltage powerlines of claim 8 wherein when the level of the atmosphere and any other contaminants being removed from the pipeline are acceptable, the filing of the pipeline.

10. The transmission pipeline for cooling high voltage powerlines of claim 9 wherein when the level of the atmosphere and any other contaminants being removed from the pipeline are acceptable, the filing of the pipeline with oil can proceed.

11. The transmission pipeline for cooling high voltage powerlines of claim 10 wherein once the entre pipeline has been filled with oil, all the valves are closed, the manifold is closed, and all equipment removed.

12. A transmission pipeline for cooling high voltage powerlines with a liquid, comprising:
a maintenance access valve installed on the pipeline for adding or removing the oil from the pipeline;
a maintenance manifold installed on the maintenance access valve depending for all purposes regarding the maintenance necessary for the pipeline at that location;
a manual service shut off valve disposed on the outlet side of the manifold;
a clear hose mounted at a first end to the outlet of the manual service shut off valve;
the clear hose mounted at a second end to a manual shutoff valve disposed on a tank within maintenance service equipment;
a liquid detection sensor installed between the clear hose and the manual shut off valve;
an electric powered shutoff valve installed between the liquid detection sensor and the manual shutoff valve wherein the electric powered shutoff valve is normally closed when no power is applied to the electric powered shutoff valve;
a pump motor connected to an outlet of the tank; and
an exhaust pipe mounted to an outlet of the pump.

13. The transmission pipeline for cooling high voltage powerlines of claim 12 wherein the liquid detection sensor communicates with the electric powered shutoff valve when liquid is present.

14. The transmission pipeline for cooling high voltage powerlines of claim 13 wherein the electric powered shutoff valve can automatically close to protect the equipment in the maintenance service equipment device.

15. The transmission pipeline for cooling high voltage powerlines of claim 14 wherein the electric powered shutoff valve can automatically close to protect environment outside of the maintenance service equipment device by preventing oil from flowing into the environment.

16. The transmission pipeline for cooling high voltage powerlines of claim 15 wherein once the entre pipeline has been filled with a total allotment of oil, then all valves are closed, the manifolds is closed and all equipment is removed.

17. The transmission pipeline for cooling high voltage powerlines of claim 16 wherein prior to the pipeline being made operational, all maintenance access valves along the pipeline are opened and connected to equipment device.

18. The transmission pipeline for cooling high voltage powerlines of claim 17 wherein the equipment device is operated to draw the atmosphere and any other contaminants from the pipeline.

19. The transmission pipeline for cooling high voltage powerlines of claim 18 wherein when the level of the atmosphere and any other contaminants being removed from the pipeline are acceptable, the filing of the pipeline.

20. The transmission pipeline for cooling high voltage powerlines of claim 19 wherein when the level of the atmosphere and any other contaminants being removed from the pipeline are acceptable, the filing of the pipeline with oil can proceed; and
once the entre pipeline has been filled with oil, all the valves are closed, the manifold is closed, and all equipment removed.
